(19) United States
(12) Patent Application Publication
(10) Pub. No.: US 2013/0052754 A1
(43) Pub. Date: Feb. 28, 2013

(54) VAPOR GROWTH METHOD AND VAPOR GROWTH APPARATUS

(71) Applicants: Kouki ZAITSU, Shizuoka-ken (JP); Yuusuke SATO, Tokyo (JP)

(72) Inventors: Kouki ZAITSU, Shizuoka-ken (JP); Yuusuke SATO, Tokyo (JP)

(21) Appl. No.: 13/597,883

(22) Filed: Aug. 29, 2012

(30) Foreign Application Priority Data
Aug. 31, 2011 (JP) 2011-189353

(51) Int. Cl. H01L 21/66; B08B 7/00; H01L 21/465

(52) U.S. Cl. 438/5; 156/345.25; 134/19; 134/18; 257/E21.528

(57) ABSTRACT

A vapor growth method includes: loading a wafer into a reaction chamber and placing the wafer on a support unit; heating the wafer with a heater provided below the support unit and controlling an output of the heater so that the wafer reaches a predetermined temperature; rotating the wafer and supplying process gas onto the wafer, thereby forming a film on the wafer; unloading the wafer from the reaction chamber; supplying etching gas into the reaction chamber and removing a reaction product deposited inside the reaction chamber by etching; and detecting an etching end point based on variation in a first temperature, which is a temperature on the support unit when the output of the heater is controlled to have a predetermined amount, or variation in the output of the heater, which is controlled so that the first temperature reaches a predetermined temperature.

### CROSS REFERENCE TO RELATED APPLICATION

This application is based upon and claims the benefit of priority from the prior Japanese Patent Application No. 2011-189353 filed in Japan on Aug. 31, 2011; the entire contents of which are incorporated herein by reference.

### FIELD

The present invention relates to a vapor growth method and a vapor growth apparatus used for forming a film by, for example, supplying reaction gas to a front face of a semiconductor wafer while heating the semiconductor wafer from a rear face thereof.

### BACKGROUND

In recent years, due to requirements for further price reduction and higher performance of semiconductor devices, there has been required higher quality, such as improvement in film thickness uniformity, as well as high productivity in a film formation process.

A single-wafer-processing type vapor growth apparatus is used to satisfy such requirements. In a single-wafer-processing type vapor growth apparatus, a film is formed on a wafer in a reaction chamber by, for example, a rear face heating method for supplying process gas while rapidly rotating the wafer at equal to or higher than 900 rpm, and heating the wafer from the rear surface thereof by using a heater.

In such a film formation process, reaction products are deposited on not only the wafer but also a holder, which is a support member of the wafer. As a consequence, dusts are scattered from the reaction products in the reaction chamber to contaminate the wafer, thereby causing a problem of a reduction in yield.

Hence, etching is applied on a regular basis inside the reaction chamber to remove the reaction products deposited (Japanese Patent Application Laid-Open No. 11-67675).

The etching is applied inside the reaction chamber on a regular basis taking into account the conditions inside the reaction chamber such as that 100 to several 100 μm of reaction products are deposited. In this regard, normally, etching gas is injected after decreasing a temperature inside the reaction chamber, unloading the wafer subjected to film formation and increasing the temperature inside the reaction chamber.

There is determined a time from the injection of etching gas to the visual removal of reaction products resulting in changes in the color on a holder. There is estimated in advance a time, as an etching time, having an overetching time for reliably removing the reaction products in addition to the above-mentioned time.

However, visual end point detection is not always accurate. Time estimation is required on a case by case basis under the environment in which the conditions frequently changes inside the reaction chamber. There is also a problem that overetching causes damages on a holder made of SiC, for example, by etching. In addition, from the aspect of improvement in productivity, reduction of the etching time is required.

Hence, it is required to provide a vapor growth method and a vapor growth apparatus capable of improving the yield and productivity by, when removing the reaction products deposited inside the reaction chamber by etching, accurately detecting an etching end point and controlling damages inside the reaction chamber.

### SUMMARY

A vapor growth method according to an aspect of the present invention includes: loading a wafer into a reaction chamber and placing the wafer on a support unit; heating the wafer with a heater provided below the support unit and controlling an output of the heater so that the wafer reaches a predetermined temperature; rotating the wafer and supplying process gas onto the wafer, thereby forming a film on the wafer ; unloading the wafer from the reaction chamber; supplying etching gas into the reaction chamber and removing a reaction product deposited inside the reaction chamber by etching; and detecting an etching end point based on variation in a first temperature, which is a temperature on the support unit when the output of the heater is controlled to have a predetermined amount, or variation in the output of the heater, which is controlled so that the first temperature reaches a predetermined temperature.

It is preferable, in the vapor growth method according to another aspect of the present invention, to detect a second temperature, which is a temperature of the wafer, upon film formation, to control the output of the heater based on the second temperature, to switch a temperature subject to detection to the first temperature after completion of the film formation, and to control the output of the heater based on the first temperature.

It is preferable, in the vapor growth method according to another aspect of the present invention, to supply etching gas while increasing a temperature of the reaction chamber.

It is preferable, in the vapor growth method according to another aspect of the present invention, that the etching end point is detected according to variation in the first temperature or the output of the heater when the reaction product is removed and the support unit is exposed.

A vapor growth apparatus according to an aspect of the present invention includes: a reaction chamber into which a wafer is loaded; a gas supply unit for supplying process gas into the reaction chamber; a gas exhaust unit for exhausting gas from the reaction chamber; a support unit on which the wafer is placed; a rotation control unit for rotating the wafer; a heater for heating the reaction chamber so that the reaction chamber reaches a predetermined temperature; a first temperature detection unit for detecting a temperature of the support unit; a second temperature detection unit for detecting a temperature of the wafer; and an etching end point detecting mechanism detecting an etching end point based on variation in temperatures detected by the first temperature detection unit or variation in the output of the heater, which is controlled based on the second temperature.

### BRIEF DESCRIPTION OF THE DRAWINGS

FIG. 1 is a cross-sectional view of a vapor growth apparatus according to an embodiment of the present invention.

FIG. 2 is a flowchart showing a process for forming a Si epitaxial film using a vapor growth apparatus according to an embodiment of the present invention.

FIG. 3 is a partly enlarged view showing the deposition of a reaction product on a holder according to an embodiment of the present invention.

FIG. 4 shows the relationship between temperature and time according to an embodiment of the present invention.

FIG. 5 is a partly enlarged view showing the relationship between heater output and time according to an embodiment of the present invention.

FIG. 6 is a partly enlarged view showing the relationship between temperature and time according to an embodiment of the present invention.

### DETAILED DESCRIPTION

Referring to the accompanying drawings, an embodiment of the present invention will be described below.

### First Embodiment

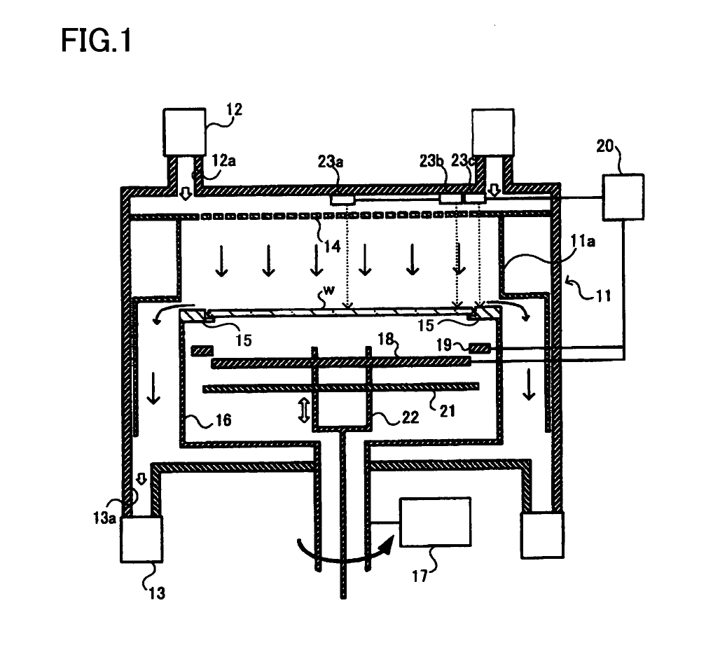

FIG. 1 illustrates a cross-sectional view of a vapor growth apparatus according to the present embodiment. As illustrated in FIG. 1, in a reaction chamber 11 in which a wafer w is subjected to film formation, there is provided a quartz cover 11a so as to cover an inner wall thereof as necessary.

At an upper portion of the reaction chamber 11, there is provided a gas supply port 12a connected to a gas supply unit 12 for supplying process gas including source gas and carrier gas. At a lower portion of the reaction chamber 11, there is disposed a gas exhaust port 13a connected to a gas exhaust unit 13 for exhausting gas to two places, for example, thereby controlling a pressure inside the reaction chamber to be constant (e.g. a normal pressure).

At a lower portion of the gas supply port 12a, there is provided a rectifying plate 14 having fine through holes for rectifying the process gas supplied and supplying the rectified gas.

At a lower portion of the rectifying plate 14, there is provided an annular holder 15, which is a support unit for placing the wafer w and is made of SiC, for example. The holder 15 is disposed on a ring 16, which is a rotation member. The ring 16 is connected, via a rotation shaft that rotates the wafer w at a predetermined rotation speed, to a rotation control unit 17, which is constituted by a motor or the like.

Inside the ring 16, there is disposed a heater for heating the wafer w, which is constituted by an in-heater 18 and an out-heater 19, which are made of SiC, for example. The heater is connected to a temperature control unit 20, which controls the in-heater 18 and the out-heater 19 so that they respectively reach a predetermined temperature at a predetermined speed of increase/decrease in temperature. There is also provided a disc-shaped reflector 21 for reflecting the heat coming downwardly from the in-heater 18 and the out-heater 19 to effectively heat the wafer w. Further, there is provided a lift pin 22, which supports a lower face of the wafer w so as to penetrate through the in-heater 18 and the reflector 21, thereby vertically moving the wafer w.

At an upper portion of the reaction chamber 11, there are disposed radiation thermometers 23a, 23b and 23c, which are temperature detection units for detecting temperature distributions of a central portion and a peripheral edge portion of the wafer wand the holder 15. The radiation thermometers 23a, 23b and 23c are connected to the temperature control unit 20. The temperature control unit 20 is herein constituted by a micro computer, for example.

Using such a vapor growth apparatus, a Si epitaxial film is formed on a φ200 mm wafer w, for example.

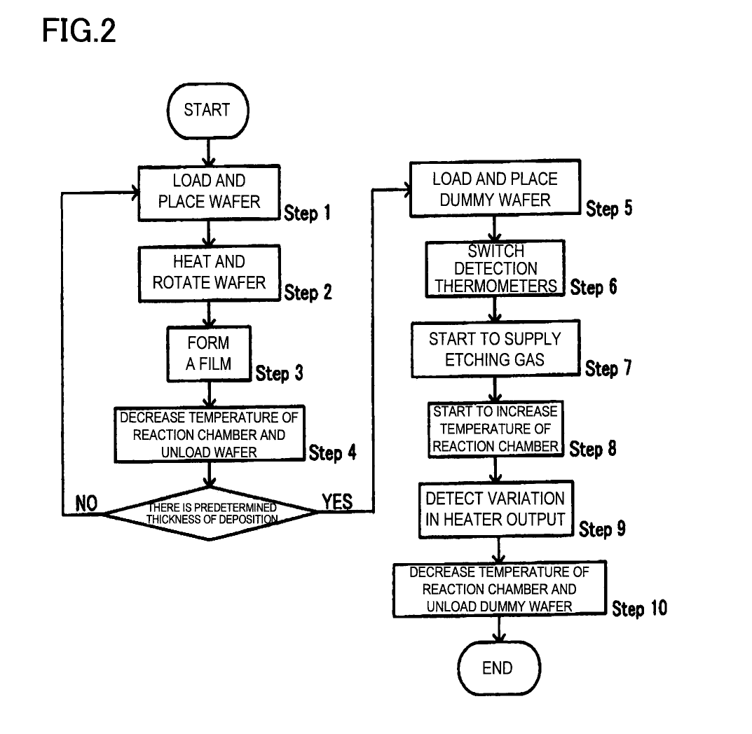

FIG. 2 is a flowchart showing a process for forming a Si epitaxial film using the above-described a vapor growth apparatus. Firstly, with a robot hand (not shown) or the like, the wafer w is loaded into the reaction chamber 11 and placed on a lift pin (now shown). Then the lift pin is lowered, thereby placing the wafer w on the holder 15 (Step 1).

The temperature control unit 20 controls respective heater outputs so that the in-heater 18 and the out-heater 19 reach 1500-1600° C., for example, enabling the heater to heat the wafer w so that the temperature of the wafer w, which is measured by the radiation thermometers 23a and 23b, reaches 1100° C., for example. At the same time, the rotation control unit 17 rotates the wafer w at 900 rpm, for example (Step 2).

The process gas, which has the flow volume controlled by the gas supply control unit 12 and is mixed, is supplied, via the rectifying plate 14, onto the wafer w in a rectified state. The process gas is supplied at 50 SLM, for example, having Dichlorosilane (SiH₂Cl₂) as Si source gas, for example, diluted by diluent gas such as H₂ gas to have a predetermined concentration (e.g. 2.5%).

On the other hand, exhaust gas including surplus process gas and reaction by-product is exhausted from the gas exhaust port 13a via the gas exhaust unit 13, thereby controlling a pressure inside the reaction chamber 11 to be constant (e.g. a normal pressure).

Thus, a Si epitaxial film having a predetermined film thickness is formed on the wafer w (Step 3). After decreasing the temperature of the reaction chamber 11 to 800° C., for example, the wafer w is unloaded from the reaction chamber 11 (Step 4).

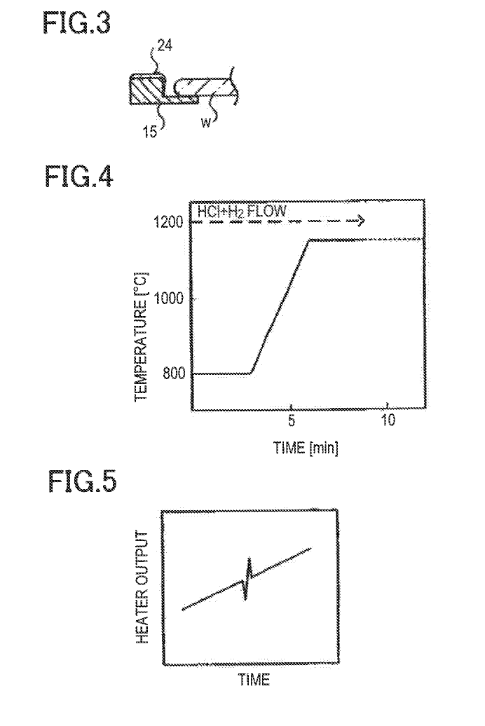

Repeated film formation in this manner causes a reaction product 24 to deposit on the holder 15 as illustrated in FIG. 3 showing the partly enlarged view thereof. Then, the reaction product 24 is removed by etching at the time when it is judged that the reaction product 24 is deposited approximately 100 to several 100 μm.

Firstly, a dummy wafer w_{d} made of SiC, for example, is loaded into the reaction chamber 11 and placed on the holder 15 (Step 5). Then, a temperature subject to detection is switched from a temperature of the wafer w, which is measured by the radiation thermometers 23a and 23b, to a temperature of the holder 15, which is measured by the radiation thermometer 23c (Step 6). HCl, as etching gas, is diluted by diluent gas such as H₂ to have predetermined contamination, and supplied (Step 7). By way of example, as illustrated in FIG. 4 showing the relationship between the temperature and the time, after 3-minute flow of the etching gas, the temperature control unit 20 controls, along with the flow of the etching gas, the respective heater outputs of the in-heater 18 and the out-heater 19 so that the temperature of the holder, which is measured by the radiation thermometer 23c, increases at 100° C./min., for example, up to 1150° C., for example (Step 8).

In this manner, the reaction product deposited on the holder 15 is removed by etching. When the holder 15 is exposed, the heater output for controlling it to reach a predetermined temperature changes, as illustrated in FIG. 5 showing a partly enlarged view of the relationship between the heater output and the time, to have a particular form (e.g. the output having a constant or linear variation once drops sharply and soars). Then, the temperature control unit 20 detects the variation in the heater output having the above-described particular form (Step 9), thereby being the etching end point. After that, the temperature of the reaction chamber 11 is decreased and the dummy wafer w_{d} is unloaded (Step 10).

It is believed that such a particular form in the heater output is caused by variation in the temperature of the holder 15 which is detected by the radiation thermometer 23c (an intensity of wavelength which is detected) when the reaction product deposited on the holder 15 is removed. At this time, in order to detect the variation in temperatures more accurately, it is preferable to use, as a radiation thermometer, a two-color thermometer that detects a temperature according to relative intensities of different wavelengths.

As described above, according to the present embodiment, the etching end point is accurately detected due to variation in the temperature of the holder which is detected when the reaction product deposited on the holder is removed. It is therefore possible to control damages inside the reaction chamber caused by overetching as well as to reduce the etching time. Accordingly, the reliable removal of the reaction product inside the reaction chamber enables improvement in yield, and the control of damages inside the reaction chamber reduces the frequency of maintenance. In addition, reduction of the etching time enables improvement in productivity.

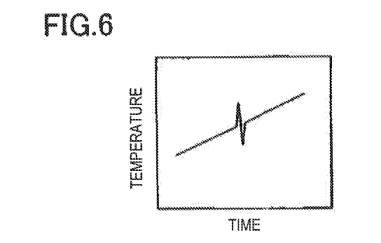

Note that, in the present embodiment, variation in the heater output is detected. However, as illustrated in FIG. 6 showing a partly enlarged view of the relationship between the temperature and the time, variation in temperatures itself may be detected by increasing the heater output in a phased manner or by maintaining a constant heater output.

In addition, in the present embodiment, it is possible to reduce the etching time by flowing the etching gas while increasing the temperature inside the reaction chamber 11, instead of a traditional way of flowing the etching gas after increasing the temperature inside the reaction chamber 11 up to a predetermined temperature. It is believed that this is because an etching rate grows with an increase in temperature, however, it is saturated in the middle of the increase in temperature. Hence, a certain level of etching rate can be obtained even when the etching gas is flowed during the increase in temperature. It is therefore possible to reduce the entire etching time.

Note that variation in the etching rate due to etching during the increase in temperature makes it difficult to accurately estimate, in advance, the time to reach the etching end point. In the present embodiment, however, there is no problem with the variation in the etching rate because it is detected that the end point has been reached.

Note that, in the present embodiment, using the annular holder 15, the dummy wafer w_{d} is placed on the holder 15 upon etching. However, it is not necessary to place the dummy wafer w_{d} when a disc-shaped susceptor is used as a support unit.

According to the embodiment described above, it is possible to form a film such as an epitaxial film on a semiconductor wafer w with high productivity in a stable manner. It is also possible to improve the yield of wafer as well as the yield of a semiconductor device formed through an element formation process and an element separation process, and stability of element characteristics. In particular, excellent element characteristics can be obtained by application of the embodiments to an epitaxial formation process for a power semiconductor device such as a power MOSFET and an IGBT, which requires film thickness growth of equal to or larger than 100 μm in a N-type base region, P-type base region, an insulation separation region or the like.

In the present embodiment, there has been described a case in which a Si epitaxial film is formed. However, the present embodiment is also applicable to a case for the formation of an epitaxial layer of other compound semiconductors such as SiC, GaN, GaAlAs and In GaAs, a polysilicon layer, or an insulation layer such as SiO₂ layer and Si₃N₄ layer. The present embodiment can be practiced in various forms without departing from the spirit and scope of the invention.

What is claimed is:

1. A vapor growth method comprising:
loading a wafer into a reaction chamber and placing the wafer on a support unit;
heating the wafer with a heater provided below the support unit and controlling an output of the heater so that the wafer reaches a predetermined temperature;
rotating the wafer and supplying process gas onto the wafer, thereby forming a film on the wafer;
unloading the wafer from the reaction chamber;
supplying etching gas into the reaction chamber
and removing a reaction product deposited inside the reaction chamber by etching; and
detecting an etching end point based on variation in a first temperature, the first temperature being a temperature on the support unit when the output of the heater is controlled to have a predetermined amount, or variation in the output of the heater, the output of the heater being controlled so that the first temperature reaches a predetermined temperature.

2. The vapor growth method according to claim 1, further comprising:
detecting a second temperature upon film formation, the second temperature being a temperature of the wafer;
controlling the output of the heater based on the second temperature;
switching a temperature subject to detection to the first temperature after completion of the film formation; and
controlling the output of the heater based on the first temperature.

3. The vapor growth method according to claim 2, further comprising:
supplying the etching gas while increasing a temperature of the reaction chamber.

4. The vapor growth method according to claim 3, wherein the etching end point is detected according to variation in the first temperature or the output of the heater when the reaction product is removed and the support unit is exposed.

5. The vapor growth method according to claim 1, further comprising supplying the etching gas while increasing the temperature of the reaction chamber.

6. The vapor growth method according to claim 5, wherein the etching end point is detected according to variation in the first temperature or the output of the heater when the reaction product is removed and the support unit is exposed.

7. The vapor growth method according to claim 1, wherein the process gas includes Si source gas.

8. The vapor growth method according to claim 1, wherein the etching gas includes HCl gas.

9. A vapor growth apparatus comprising:
a reaction chamber configured to load a wafer;
a gas supply unit configured to supply process gas into the reaction chamber;
a gas exhaust unit configured to exhaust gas from the reaction chamber;
a support unit configured to place the wafer;
a rotation control unit configured to rotate the wafer;
a heater configured to heat the reaction chamber so that the reaction chamber reaches a predetermined temperature;
a first temperature detection unit to detect a temperature of the support unit;
a second temperature detection unit to detect a temperature of the wafer; and
an etching end point detecting mechanism configured to detect an etching end point based on variation in temperatures detected by the first temperature detection unit or variation in the output of the heater, the output of the heater being controlled based on the first temperature.

10. The vapor growth apparatus according to claim 9, wherein the first temperature detection unit is disposed to enable detection of a temperature of the support unit to place the wafer, and the second temperature detection unit is disposed to enable detection of a temperature of the wafer placed on the support unit.

11. The vapor growth apparatus according to claim 10, wherein the first and the second temperature detection units are radiation thermometers.

12. The vapor growth apparatus according to claim 11, wherein the radiation thermometer constituting the first temperature detection unit is a two-color thermometer, the two-color thermometer detecting a temperature according to relative intensities of different wavelengths.

13. A method for cleaning a vapor growth apparatus comprising:
unloading a wafer after a film is formed on the wafer inside a reaction chamber;
supplying etching gas into the reaction chamber and removing a reaction product deposited inside the reaction chamber by etching;
controlling an output of an heater, thereby controlling a temperature in the reaction chamber; and
detecting an etching end point based on variation in a first temperature, the first temperature being a temperature on the support unit when the output of the heater is controlled to have a predetermined amount, or variation in the output of the heater, the output of the heater being controlled so that the first temperature reaches a predetermined temperature.

14. The method for cleaning a vapor growth apparatus according to claim 13, further comprising controlling the output of the heater based on the first temperature.

15. The method for cleaning a vapor growth apparatus according to claim 14, further comprising supplying the etching gas while increasing a temperature of the reaction chamber.

16. The method for cleaning a vapor growth apparatus according to claim 15, wherein the etching end point is detected according to variation in the first temperature or the output of the heater when the reaction product is removed and the support unit is exposed.

17. The method for cleaning a vapor growth apparatus according to claim 13, further comprising supplying the etching gas while increasing the temperature of the reaction chamber.

18. The method for cleaning a vapor growth apparatus according to claim 17, wherein the etching end point is detected according to variation in the first temperature or the output of the heater when the reaction product is removed and the support unit is exposed.

19. The method for cleaning a vapor growth apparatus according to claim 13, wherein the process gas includes Si source gas.

20. The method for cleaning a vapor growth apparatus according to claim 13, wherein the etching gas includes HCl gas.
